(19) United States
(12) Patent Application Publication
(10) Pub. No.: US 2023/0207377 A1
(43) Pub. Date: Jun. 29, 2023

(54) SEMICONDUCTOR PROCESSING DEVICE WITH WAFER EDGE PURGING

(71) Applicant: ASM IP Holding B.V., Almere (NL)

(72) Inventors: Rohan Vijay Rane, Tempe, AZ (US); Herbert Terhorst, Amersfoort (NL); Eric James Shero, Phoenix, AZ (US); Ankit Kimtee, Phoenix, AZ (US); Jereld Lee Winkler, Gilbert, AZ (US); Michael Schmotzer, Chandler, AZ (US); Shuyang Zhang, Chandler, AZ (US); Todd Robert Dunn, Cave Creek, AZ (US); Shubham Garg, Tempe, AZ (US)

(21) Appl. No.: 18/087,871

(22) Filed: Dec. 23, 2022

Related U.S. Application Data
(60) Provisional application No. 63/266,099, filed on Dec. 28, 2021.

(51) Int. Cl. H01L 21/687; C23C 16/44

(52) U.S. Cl. CPC H01L 21/68735; C23C 16/4408; H01L 21/68785

(57) ABSTRACT

A semiconductor processing device comprises a susceptor assembly comprising a wafer support configured to support a wafer. The wafer support comprises a wafer support body configured to support the wafer, a purge channel extending laterally from an inner portion of the wafer support body to an outer portion of the wafer support body, a first plenum channel disposed at the outer portion of the wafer support and in fluid communication with the purge channel, and an outlet to deliver purge gas to an edge of the wafer, the outlet in fluid communication with the first plenum channel, a purge gas supply hole on a surface opposite to the wafer support body. The purge gas supply hole is in fluid communication with the purge channel, and a plurality of first purge holes fluidly communicated with the first plenum channel and the purge channel.

### CROSS-REFERENCE TO RELATED APPLICATIONS

This application is a nonprovisional of, and claims priority to and the benefit of, U.S. Provisional Patent Application No. 63/266,099, filed Dec. 28, 2021 and entitled “SEMICONDUCTOR PROCESSING DEVICE WITH WAFER EDGE PURGING,” which is hereby incorporated by reference herein.

### FIELD

The field relates to a semiconductor processing device with wafer edge purging. For example, the field is generally related to a susceptor assembly that includes one or more channels to deliver a purge gas to an edge of a semiconductor wafer. Additionally or alternatively, the field relates to a showerhead assembly configured to supply a reactant gas to a front surface of the semiconductor wafer and a purge gas to the edge of the wafer.

### BACKGROUND

During semiconductor processing, various vaporized precursor(s) are fed into a reaction chamber. In some applications, suitable source chemicals that are in solid or liquid phase at ambient pressure and temperature are provided in a source vessel. These solid or liquid source substances may be heated to sublimation or evaporation to produce a vaporized precursor for a reaction process, such as vapor deposition. Chemical Vapor Deposition (CVD) may call for the supply of continuous streams of precursor vapor to the reaction chamber, while Atomic Layer Deposition (ALD), pulsed CVD and hybrids thereof may call for continuous streams or pulsed supply to the reaction chamber, depending on the desired configuration.

### SUMMARY

In view of the above-mentioned situation, one object of one or more aspects of the disclosed embodiments is to provide a susceptor assembly to eliminate any backside wafer deposition.

In some embodiments, the susceptor assembly may include a wafer support configured to support a wafer, which may comprise a wafer support body configured to support the wafer on a support surface of the wafer support body. The wafer support may further comprise a purge channel extending laterally from an inner portion of the wafer support body to an outer portion of the wafer support body and a first plenum channels disposed at the outer portion of the wafer support being in fluid communication with the purge channel, and an outlet to deliver purge gas to an edge of the wafer, said outlet is fluidly communicated with the first plenum channel. The susceptor assembly may further comprise a purge gas supply hole on a surface opposite to the support surface of the wafer support body, said purge gas supply hole being in fluid communication with the purge channel, and a plurality of first purge holes fluidly communicated with the first plenum channel and the purge channel. The wafer support may comprise a cylindrical body and the outlet may be concentric with the wafer support and a plurality of the purge channels extending symmetrically from the inner portion.

In some embodiments, the wafer support body may comprise a recess portion configured to support the wafer, and the outlet may be formed on the recess portion and in fluid communication with the first plenum. The wafer support may further comprise an annular ridge on the recess portion, and said annular ridge may be concentric with a circumference of the wafer to be treated. Said annular ridge may be configured to be disposed within a perimeter of the wafer to be treated. The outlet may be formed along an outermost periphery of the annular ridge. A depth of the recess portion at an outer diameter side of the annular ridge may be deeper than an inner diameter side of the annular ridge and progressively decreased toward a perimeter of the cylindrical body.

In some embodiments, a second plenum channel may be formed at the outer portion of the wafer support which is positioned vertically apart from the first plenum in a thickness direction of the wafer support body. The wafer support may further comprise a plurality of second purge holes providing fluidly communicated with the first plenum channel and the second plenum channel. The plurality of first purge holes may be fluidly communicated with second plenum channel and respective purge channels. A number of the second purge holes may be greater than a number of the first purge holes.

In some embodiments, the susceptor assembly may be coupled to a shaft which comprises a vacuum tube and an inner gas supply tube, and a plurality of purge gas supply holes may be configured to be fluidly connected to an inert gas source through the inner gas supply tube. The wafer support body may comprise a Nickel-Chromium Molybdenum alloy. The susceptor assembly may further comprise a vacuum chuck groove disposed at the inner portion of the wafer support and a vacuum chuck hole in fluid communication with a plurality of vacuum chuck grooves through the vacuum tube. The vacuum chuck hole may be configured to be in fluid connection with a vacuum source. The wafer support body may comprise Hastelloy® C22® material.

In some embodiments, a susceptor assembly may comprise a wafer support configured to support a wafer, which may comprise a wafer support body configured to support a wafer to be treated, a plurality of purge channels extending laterally from an inner portion of the wafer support body to an outer portion of the wafer support body, a first plenum channel disposed at the outer portion of the wafer support, and a second plenum channel positioned vertically apart from the first plenum. The susceptor assembly may further comprise a second plenum channel which is in fluid communication with the plurality of purge channels by way of a plurality of first purge holes and in fluid communication with the first plenum by way of a plurality of second purge holes and an outlet in fluid communication with the first plenum to deliver purge gas to an edge of the wafer. The wafer support body may comprise a recess portion configured to support the wafer, and the outlet may be formed on the recess portion and in fluid communication with the first plenum. The susceptor assembly may be coupled to a shaft which comprises a purge gas supply tube connected to an inert gas source.

In some embodiments, a susceptor assembly may comprise a cap and a heater pedestal, wherein the cap comprises the wafer support and the surface opposite to the recess portion is configured to be disposed on a heater pedestal. The wafer support body may comprise a recess portion configured to support the wafer, and the outlet is formed on the recess portion and in fluid communication with the first plenum. The heater pedestal may be coupled to a shaft which comprises a vacuum tube and an inner gas supply tube. The heater pedestal may comprise one or more vacuum holes configured to couple to the respective vacuum chuck holes, and one or more purge gas holes configured to couple to the respective purge gas supply holes. The one or more vacuum holes may be configured to be fluidly connected to a vacuum source through the vacuum tube, and the one or more purge holes may be configured to be fluidly connected to an inner gas source through the inner gas supply tube. The susceptor assembly may comprises three temperature control zones which allows better tuning of the outer portion and improve within wafer (WiW)NU %.

Another object of one or more aspects of the present invention is to provide a showerhead assembly for treating a wafer which prevents back diffusion so that backside wafer deposition is eliminated.

In some embodiments, the showerhead assembly may comprise a showerhead plenum, a plurality of openings in fluid communication with the showerhead plenum, and an edge purge injection holes configured to be disposed outside of a perimeter of the wafer to be treated and in fluid communication with a purge gas source. The plurality of openings may be configured to convey vaporized precursor(s) from the showerhead plenum and onto a wafer support configured to support the wafer and the edge purge injection hole may be arranged to direct a purge gas to prevent back-diffusion of gases to the wafer.

In some embodiments, the showerhead assembly may include the plurality of edge purge injection holes are directed circumferentially outwardly relative to the wafer to be treated. The showerhead assembly may further comprise a plurality of edge purge injection holes. The edge purge injection hole may not be in fluid communication with the showerhead plenum.

In some embodiments, a showerhead assembly, for treating a wafer, may comprise a showerhead plenum, a plurality of openings in fluid communication with the showerhead plenum, the plurality of openings configured to convey a vaporized precursor from the showerhead plenum and onto the wafer; and an edge purge injection hole configured to be disposed outside of a perimeter of the wafer to be treated and in fluid communication with a purge gas source. The purge gas may be directed circumferentially outwardly relative to the wafer support. The showerhead assembly may further comprise a plurality of edge purge injection holes.

In some embodiments, a showerhead assembly, for treating a wafer, may comprise a showerhead plenum, a substrate support configured to support the wafer, and a plurality of openings in fluid communication with the showerhead plenum and disposed over the substrate support. The plurality of openings may be configured to convey a vaporized precursor from the showerhead plenum and onto the wafer. A gap between the showerhead assembly and the substrate support may be narrower at an outer edge of the showerhead assembly than over the substrate support. The gap may be at least partially defined by a recess portion and a depth of the recess portion is progressively varied (e.g., decreased) toward an outer edge of the showerhead.

Yet, another object of one or more aspects of the present invention is to provide a method for purging an edge of wafer.

In some embodiments, the method may include placing a wafer to be treated on a support surface of a wafer support, delivering a purge gas laterally along a purge gas channel of the wafer support to an outer portion of the wafer support, and directing the purge gas upwardly from the purge channel through a first plenum and through an outlet to an outer edge of the wafer. The method may further comprise holding the wafer onto the wafer support by applying vacuumed to a vacuum chuck and applying precursor gas to the wafer. The purge gas may be directed from the purge channel through the first plenum, a second plenum and an outlet.

In some embodiments, the method may comprise placing a wafer to be treated on a substrate support, providing a precursor gas to the wafer from a showerhead, and delivering a purge gas through an edge purge injection hole outside of a perimeter of the wafer to be treated. The purge gas may be directed circumferentially outwardly.

In some embodiments, the method may comprise placing a wafer to be treated on a substrate support, providing a precursor gas to the wafer from a showerhead, and directing the precursor gas laterally relative to the showerhead through a gap between the showerhead and the substrate support, the gap narrower at an outer edge of the showerhead than over the wafer.

### BRIEF DESCRIPTION OF THE DRAWINGS

The foregoing and other objectives and advantages will appear from the description to follow. In the description reference is made to the accompanying drawing, which forms a part hereof, and in which is shown by way of illustration specific embodiments in which the disclosed embodiments may be practiced. These embodiments will be described in sufficient detail to enable those skilled in the art to practice the disclosed embodiments, and it is to be understood that other embodiment may be utilized and the structural changes may be made without departing from the scope of the disclosed embodiments. The accompanying drawings, therefore, are submitted merely as showing the preferred exemplification of the disclosed embodiments. Accordingly, the following detail description is not to be taken in a limiting sense, and the scope of the disclosed embodiments is best defined by the appended claims.

FIG. 1 is a schematic diagram of an overview of the overall system of a semiconductor processing device.

FIG. 2 is a schematic diagram of a susceptor assembly in accordance with one embodiment.

FIG. 3 is a schematic diagram of a wafer support showing the purge channels.

FIG. 4 is a cross-sectional view of a single plenum embodiment taken along line A-A of FIG. 3.

FIG. 5 is a cross-sectional view of a dual plenum embodiment taken along line A-A of FIG. 3.

FIG. 6 is a schematic diagram of a susceptor assembly disposed on a heater pedestal in accordance with one embodiment.

FIG. 7 is a schematic diagram of a showerhead assembly with edge purge injection holes according to one embodiment.

FIG. 8 is a schematic diagram of a showerhead assembly with edge purge injection holes directed toward an outer circumferential side according to one embodiment.

FIG. 9 is a schematic diagram of a showerhead assembly without edge purge injection holes according to one embodiment.

### DETAILED DESCRIPTION

In the following detailed description, numerous specific details are set forth in order to provide a thorough understanding of the embodiments. However, it will be obvious to one with ordinary skill in the art that the embodiments may be practiced without these specific details. In other instances, well known methods, procedures, components, and mechanism have not been described in detail as not to unnecessarily obscure aspects of the present invention.

In general, in these apparatuses used in formation of a film in semiconductor manufacturing steps, a susceptor and heat source can be arranged under a wafer, and a rear-surface heating method which can supply a uniform process gas from the top is used, which may create film growth on a backside of the wafer. During deposition processes, a high thickness on a wafer edge is observed for some processes due to backside deposition caused by back diffusion of precursors from a dead volume behind the wafer. Purging the wafer edge from a backside of the wafer will eliminate deposition on the backside of the wafer and also allow better tuning of wafer edge thickness. In order to enable backside purge and secure the wafer to the susceptor during processing, a vacuum chucking susceptor or an electrostatic chucking susceptor can be provided to hold the wafer while purging the backside can be used. The susceptor can also comprise or serve as a heater to heat the wafer during processing.

For example, a vacuum chuck aluminum nitride (AlN) susceptor heater can be used, however, a dedicated edge purge channel may not be available with the AlN heater due to poor machinability and durability. A flow from the lower chamber caused by the pressure difference between upper and lower chamber can be utilized to prevent backside deposition. However, it is difficult to control the flow and only control a limited flow rate range can be provided using pressure differentials. Further, as the geometry of the AlN heater is a ceramic, the AlN heater cannot have an edge bias of greater than 10° C. without breakage and may have only a 2-zone temperature control. For certain processes, that causes degrading an emissivity and thickness non-uniformity (NU %), which cannot be recovered by outer zone susceptor temperature tuning. Thus, there is a need in the art for susceptor assembly that provides an enhancement of tuning of wafer edge thickness.

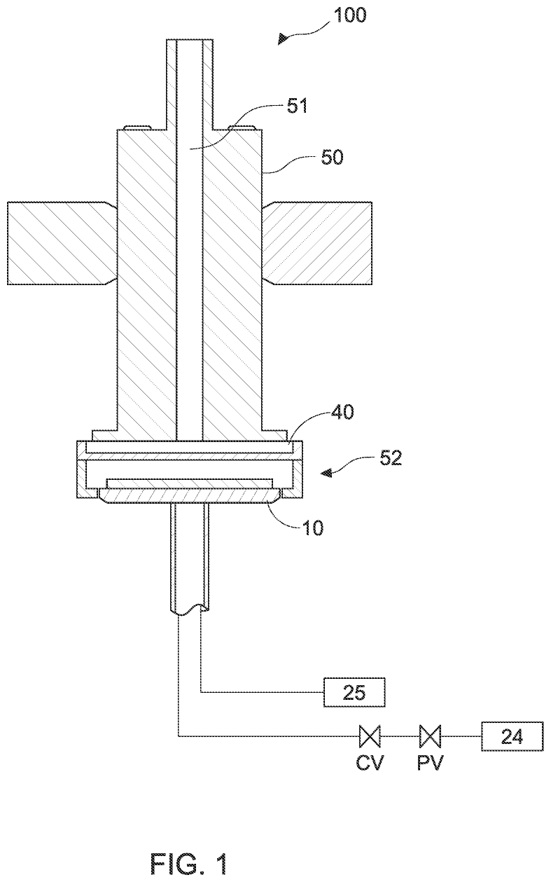

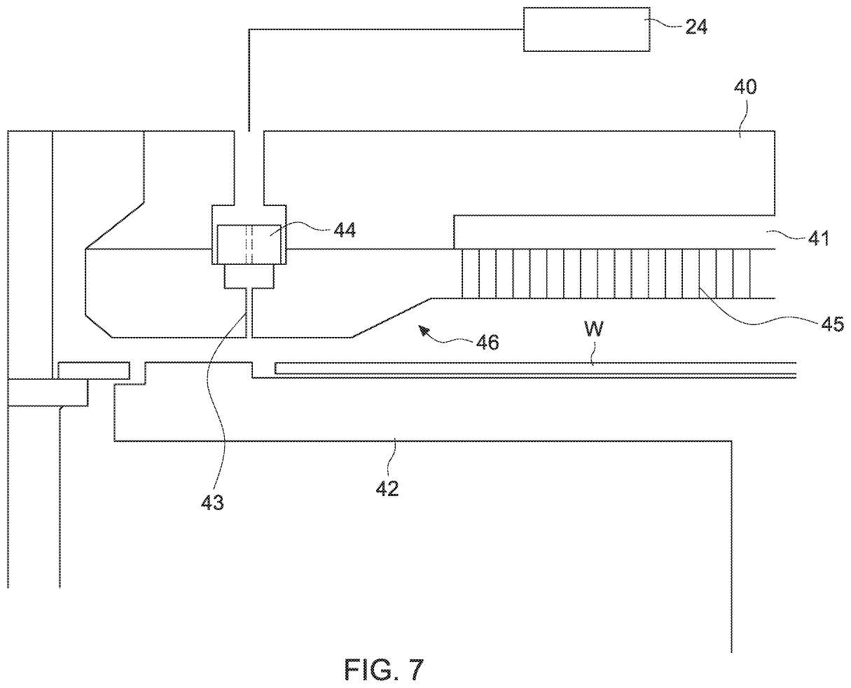

FIG. 1 is a schematic diagram of a semiconductor processing device 100 illustrating a manifold 50 as part of the overall semiconductor processing device 100. The manifold 50 can include a bore 51 that injects vaporized precursor downwards towards a showerhead assembly 40. It is understood that the manifold 50 can include multiple blocks connected together, or can comprise a unitary body. The manifold 50 can be connected upstream of a reaction chamber 52. In particular, an outlet of the bore can communicate with a reactant injector, particularly the dispersion mechanism in the form of the showerhead assembly 40. As shown in FIGS. 7-9, the showerhead assembly 40 can include a showerhead plenum 41. The showerhead assembly 40 delivers the vapored precursor from the manifold 50 to a reaction space below the showerhead 40. The reaction chamber 52 includes a wafer support 10 configured to support a substrate W (e.g., a semiconductor wafer) in the reaction space. A vacuum source 25 may be coupled to the wafer support 10 for securing the wafer and an inner gas source 24 may be couples to the wafer support for wafer edge purging through valves (CV, PV). While shown with a single-wafer, showerhead type of reaction chamber, the skilled artisan will appreciate that the manifold can also be connected to other types of reaction chambers with other types of injectors, e.g., batch or furnace type, horizontal or cross-flow reactor, etc.

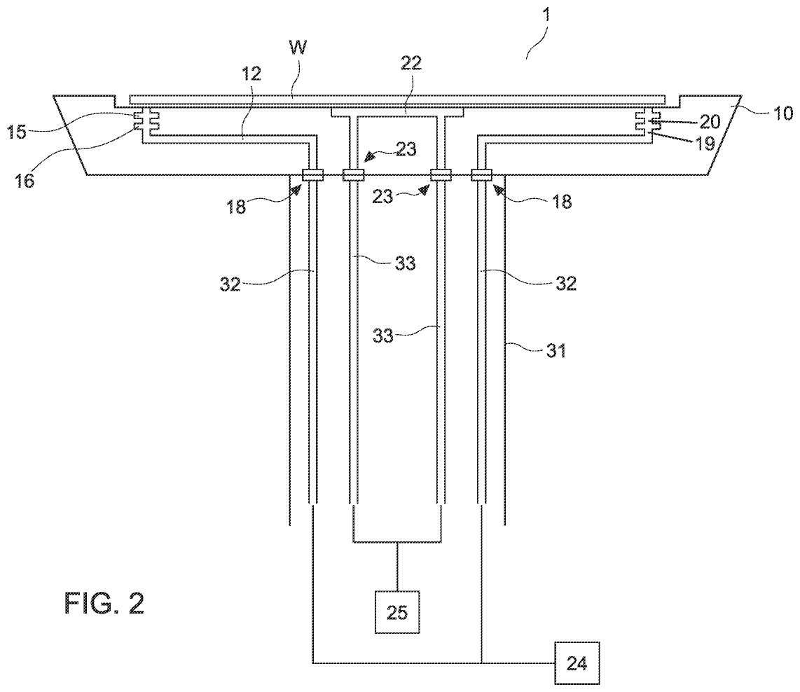

FIG. 2 is a schematic diagram of a susceptor assembly 1 in accordance with one embodiment. The susceptor assembly 1 can be configured to support a wafer W during a processing treatment. The susceptor assembly 1 can comprise a wafer support 10, which may comprise a wafer support body 11 configured to support the wafer W to be treated on a support surface of the wafer support body 11. The support surface of the wafer support body 11 may comprise a recess portion to support the wafer W. The susceptor assembly 1 may further comprise a plurality of first purge holes 19 in fluid communication with the first plenum channel 15 and the purge channel 12.

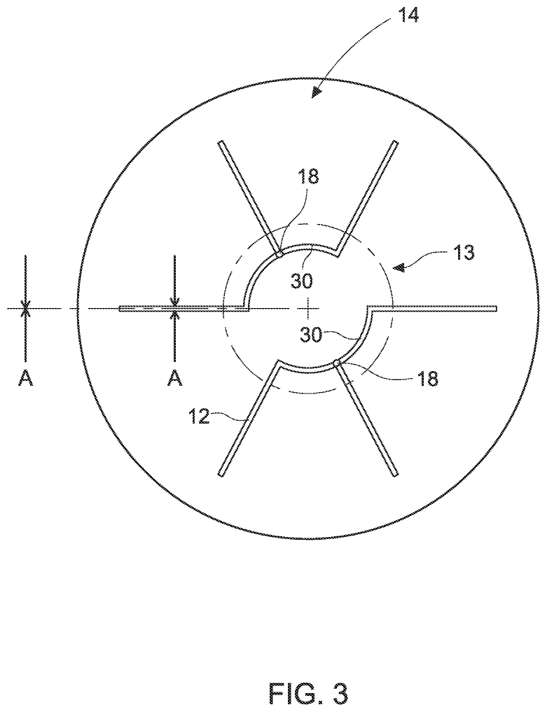

FIG. 3 is a schematic diagram of the wafer support 10 showing a purge channel 12 extending from an inner portion 13 to an outer portion 14 of the wafer support 10. The wafer support may comprise a plurality of the purge channels extending symmetrically from the inner portion.

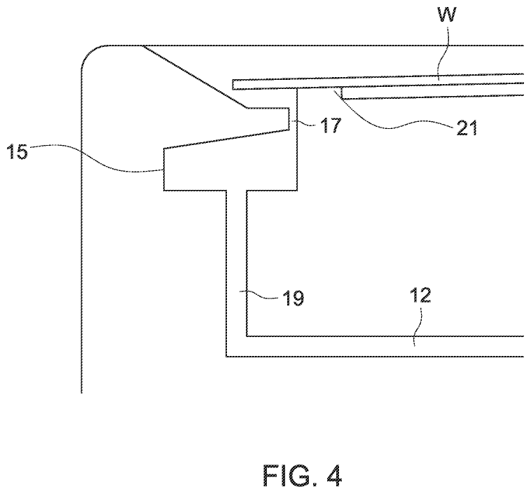

The wafer support 10 may further comprise one or more first plenum channels 15 formed at the outer portion 14 of the wafer support 10. As indicated in FIG. 4, an outlet 17 to deliver purge gas to the edge of the wafer W may be provided at or formed on the recess portion of the support surface of the wafer support body 11. The outlet 17 can be in fluid communication with the first plenum channel 15. One or more purge gas supply holes 18 (e.g., a plurality) can be formed on a surface of the wafer support 10 opposite to the recess portion of the support surface of the wafer support body 11 that supports the wafer W. The purge gas supply holes 18 can be in fluid communication with the plurality of purge channels 12 and respective inner gas supply tubes 32. The wafer support 10 may further comprise a plurality of first purge holes 19 in fluid communication with the first plenum channel 15 and the respective purge channels 12. The wafer support 10 may comprise a cylindrical or disc-shaped body and the outlet 17 may be concentric with the wafer support 10. The recess portion of the support surface of the wafer support body 11 may be shaped to receive the wafer W, such that the recess portion of the support surface of the wafer support body 11 may be generally circular in shape.

As shown in FIG. 3, the purge gas supply holes 18 may be formed on a surface opposite to the recess portion of the support surface of the wafer support body 11. The purge gas supply holes 18 can communicate with the plurality of purge channels 12 through one or more annular channels 30. The plurality of purge channels 12 may radially extend from the annular channels 30 disposed in the inner portion 13. In the illustrated embodiment, the purge channels 12 may extend symmetrically from the inner portion 13 for even distribution of the purge gas. A plurality of primary purge holes 19 can be disposed at an end of the respective purge channels 12 and in fluid communication with the first plenum channel 15, as shown in FIG. 4.

FIG. 4 illustrates the susceptor assembly with a single plenum channel, e.g., the first plenum channel 15. As shown in FIG. 4, an annular ridge 21 may be disposed on the recess portion of the support surface of the wafer support body 11 and may be concentric with a circumference of the wafer to be treated and configured to be disposed within a perimeter of the wafer W to be treated. The outlet 17 may be formed along an outermost periphery of the annular ridge 21 and may be fully opened around the circumference of the annular ridge 21. A depth of the recess portion of the support surface of the wafer support body 11 at an outer diameter side of the annular ridge 21 can be deeper than an inner diameter side of the annular ridge 21 and progressively decreased toward a perimeter of the cylindrical body.

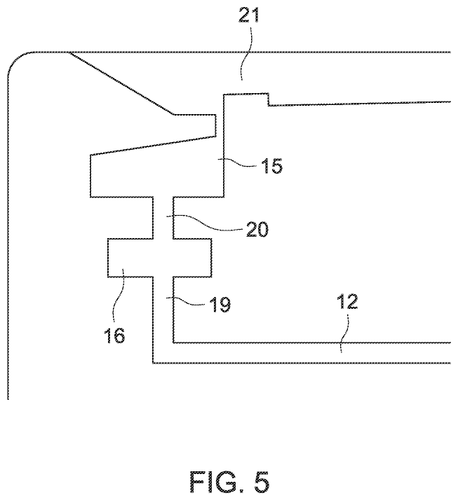

FIG. 5 illustrates a susceptor assembly with a plurality of plenum channels, e.g., the first plenum channel 15 and a second plenum channel 16. The second plenum channel 16 may be formed at the outer portion 14 of the wafer support 10, which is positioned vertically apart from the first plenum 15 in a thickness direction of the wafer support 10. The first plenum channel 15 and the second plenum channel 16 may be in fluid communication through a plurality of second purge holes 20 which may be formed through the body of the wafer support 10, as shown in FIGS. 2 and 5. The second plenum channel 16 allows the gases to combine for better distributed flow and can also provide a continuous fluid connection to the wafer edge by way of the outlet 17. Any number of the first purge holes 19 can be suitable but it may be preferable to have a large number of the purge holes for increasing uniformity. The plenums 15, 16 may be at least partially annular (e.g., completely annular) in shape, and may be configured to be disposed around the periphery of the wafer W to be treated. In some embodiments, a number of the first purge hole 19 may be equal to a number of symmetric purge channels 12 and a number of the second purge hole 20 may be greater than the number of the first purge hole 19. For example, the number of the first purge hole 19 and the number of symmetric purge channels 12 may be 6, while the number of the second purge hole 20 may be 36. The at least two purge gas supply holes 18 may be configured to be fluidly connected to the inert gas source 24.

The susceptor assembly 1 may be coupled to a shaft 31 which comprises a vacuum tube 33 and one or more inner gas supply tubes 32. The purge gas supply holes 18 may be configured to fluidly connect to the inert gas source 24 through the inner gas supply tube 32. The inert gas can be delivered from the inert gas source vertically upward through the supply tube 32 within the shaft and to the purge channels 12 through the supply holes 18. The inert gas may be delivered laterally outward to the plurality of primary purge holes 19 through the purge channels 12. The inert gas may be supplied to the first plenum 15 through the plurality of primary purge holes 19 and delivered to the second plenum channel 16 through the plurality of secondary purge holes 20 for the multiple plenum embodiment of FIG. 5. For the single plenum embodiment of FIG. 4, the channels 12 can convey the inert gas to the first plenum 15 by way of the purge holes 19. The delivered inert gas can be diffused through the outlet 17 to deliver a uniform flow to the edge of the wafer W. A narrow outlet design helps avoids dilution of the wafer edge. Beneficially, therefore, the disclosed embodiments can deliver an inert purge gas to the edge of the wafer to purge the backside of the wafer W of deposits.

The susceptor assembly 1 may further comprise one or a plurality of vacuum chuck grooves 22 disposed at the inner portion 13 of the wafer support 10. The plurality of vacuum chuck grooves 22 may be in fluid communication with at least two vacuum chuck holes 23 through vacuum tubes 32 in a shaft 31 so that the vacuum chuck grooves 22 apply suction to the wafer W to be treated. In other embodiments, the susceptor assembly 1 can comprise an electrostatic chuck to support the wafer W.

The wafer support 10 may comprise a Nickel-Chromium Molybdenum alloy having a good machinability, durability. The disclosed alloy can have a higher ramp rate per min compared to other materials (such as aluminum nitride (AlN)) for the susceptor heater, which allows a narrow slit design for outlet 17 to deliver a uniform flow to the edge of the wafer and a plurality of (e.g., three) temperature control zones, namely, the inner portion, outer portion and a portion therebetween, which allows better tuning of the outer portion and improve within wafer (WiW) non-uniformity (NU %). In some embodiments, the Nickel-Chromium Molybdenum alloy may comprise Hastelloy® C22® material, sold by Central States Industrial of Springfield, Mo.

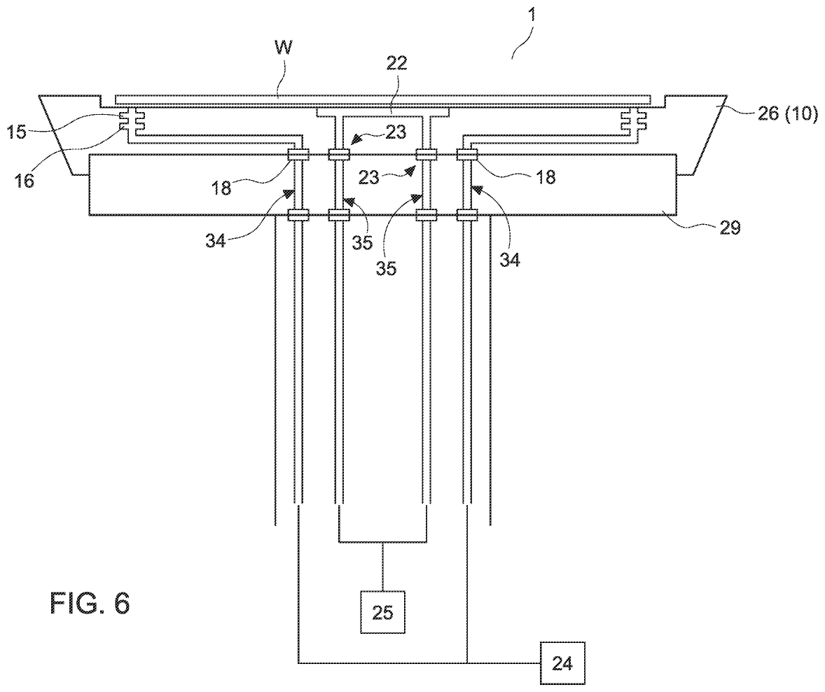

FIG. 6 illustrates another embodiment of the susceptor assembly 1. Unless otherwise noted, the components of FIG. 6 may be the same as or generally similar to like-numbered components of FIGS. 1-4. In the embodiment depicted in FIG. 6, the wafer support 10 can comprise a cap portion 26 coupled to a heater pedestal 29. As shown, the surface of the cap portion 26 opposite to the recess portion of the support surface of the wafer support body 11 of the wafer support 10 may be configured to be disposed on the heater pedestal 29. The heater pedestal 29 may comprise one or more vacuum holes 35 configured to couple to the respective vacuum chuck holes 23, and one or more purge gas holes 34 configured to couple to the respective purge gas supply holes 18. The vacuum holes 35 may be configured to be in fluid communication with a vacuum source 25 and the purge gas holes 34 may be configured to be fluidly connected to an inert gas source 24. The heater pedestal 29 may comprises Nickel-Chromium Molybdenum alloy. The Nickel-Chromium Molybdenum alloy may comprise Hastelloy® C22® material. In this manner, an expensive and cumbersome cleaning process to remove deposits from the heater can be avoided and may eliminate the effect of wafer-heater dead volume. The cap 26 may be coupled to the heater pedestal 29 by any suitable way known in the art, e.g., by way of mechanical connectors, an adhesive, etc.

FIG. 7 illustrates another embodiment for preventing deposition of reactant gasses onto the edge of the wafer W in a non-uniform manner. In FIG. 7, a showerhead assembly 40 for treating the wafer W can be disposed over a substrate support 42. The showerhead assembly 40 may comprise a showerhead plenum 41 disposed in an inner portion of the showerhead assembly 40 and a plurality of openings 45 formed on a surface facing the wafer W to be treated. The plurality of openings 45 are in fluid communication with the showerhead plenum 41 so that vaporized precursor(s) can be fed into the showerhead plenum 41 and deposited onto the wafer W through the plurality of openings 45. A plurality of edge purge injection holes 43 can be provided or formed on the surface facing the wafer W to be treated. The plurality of edge purge injection holes 43 may be located outside of a perimeter of the wafer W to be treated and in fluid communication with the inner gas source 24. In the illustrated embodiment, the edge purge injection holes 43 may be disposed outside of (and not exposed to) the showerhead plenum 41. The purge gas can be provided on the outside of a perimeter of the wafer W through an edge purge distribution perforated plate 44 so as to prevent a back diffusion from a desorption process that can migrate to the edge of the wafer W to create non-uniformity issue. The inert purge gas delivered to the edge of the wafer can beneficially create a curtain of inert gas to block back diffusion from exposing the wafer and dilutes precursor enough to lower or prevent backside deposition.

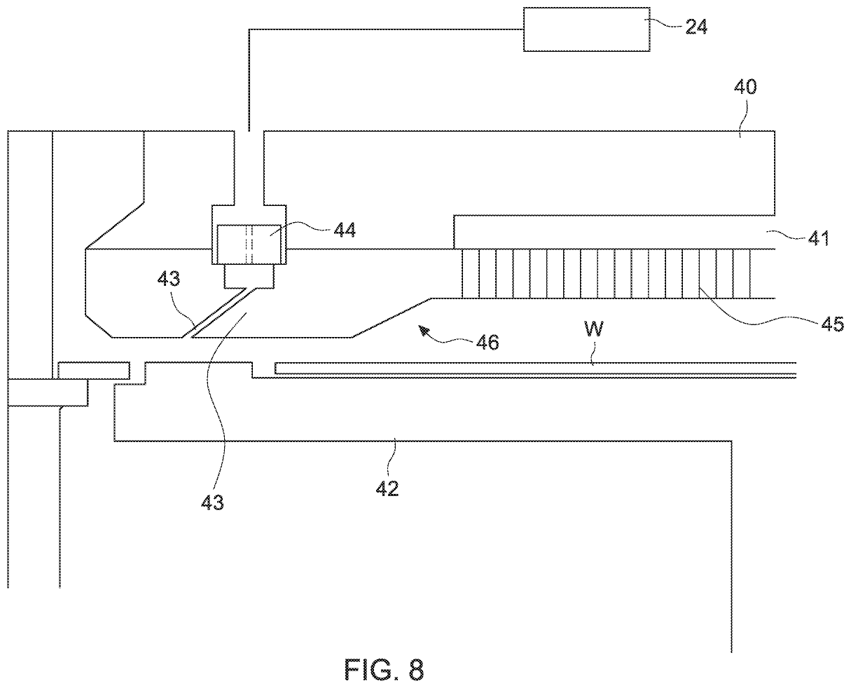

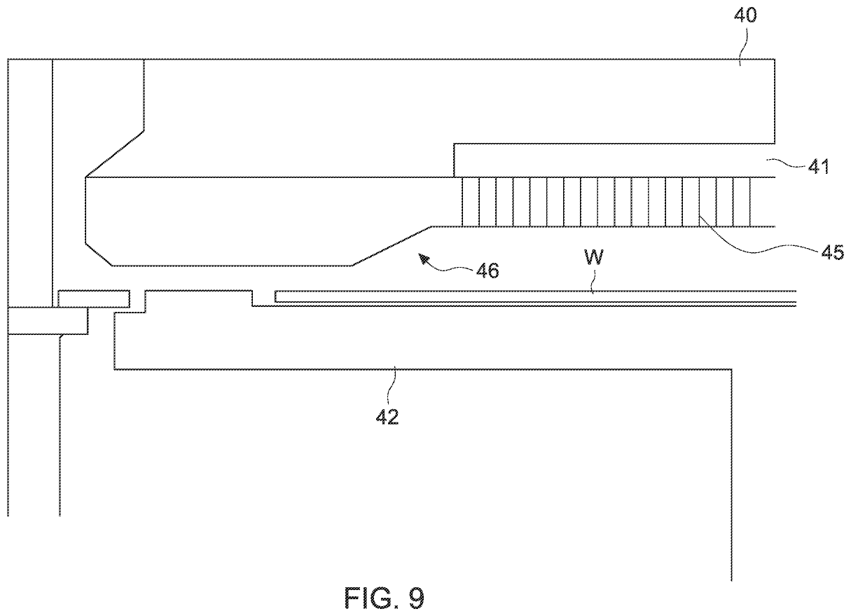

As shown in FIG. 8, the plurality of edge purge injection holes 43 may be directed toward an outer circumferential side so as to prevent back-diffusion than backside deposition. The edge purge injection holes 43 can be angled circumferentially outwardly so as to create a diffusion curtain to prevent back-diffusion of gases. Further, as indicated in FIG. 9, the showerhead assembly 40 may comprise a recess portion 46 and a depth of the recess portion can be progressively decreased toward an outer edge of the showerhead. The illustrated configuration provides a choke to compress the streamlines of gas so as to use velocity to stop back-diffusion without the edge purge injection holes 43. A gap between the showerhead assembly 40 and the substrate support can be narrower at an outer edge of the showerhead assembly 40 than over the substrate support. At the choked portion, a higher velocity and lower residence time of the vapored precursor can be achieved. Thus, the precursor can move faster, which may prevent non-uniform deposition of the precursor onto the wafer W.

The present disclosure also relates to methods for purging an edge of wafer using the susceptor assembly or showerhead assembly described herein, such as semiconductor wafers, in gas-phase reactors, such as chemical vapor deposition (CVD) reactors, including plasma-enhanced CVD (PECVD) reactors, low-pressure CVD (LPCVD) reactors, atomic layer deposition (ALD) reactors, and the like. By way of examples, the assemblies and components described herein can be used in showerhead-type gas-phase reactor systems, in which gasses generally flow in a downward direction from a showerhead and toward a substrate.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, and within less than 0.01% of the stated amount.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted fairly based on the language employed in the claims and not limited to the examples described in the present specification or during the prosecution of the application, which examples are to be construed as non-exclusive.

What is claimed is:

1. A susceptor assembly, comprising:
a wafer support configured to support a wafer, the wafer support comprising:
a wafer support body configured to support the wafer on a support surface of the wafer support body;
a purge channel extending laterally from an inner portion of the wafer support body to an outer portion of the wafer support body;
a first plenum channel disposed at the outer portion of the wafer support and in fluid communication with the purge channel; and
an outlet to deliver purge gas to an edge of the wafer, the outlet in fluid communication with the first plenum channel.

2. The susceptor assembly according to claim 1, further comprising:
a purge gas supply hole on a surface opposite to the support surface of the wafer support body, the purge gas supply hole in fluid communication with the purge channel; and
a plurality of first purge holes providing fluid communication between the first plenum channel and the purge channel.

3. The susceptor assembly according to claim 1, wherein the wafer support comprises a cylindrical body and the outlet is concentric with the wafer support.

4. The susceptor assembly according to claim 1, wherein the wafer support comprises a plurality of the purge channels extending symmetrically from the inner portion.

5. The susceptor assembly according to claim 1, wherein the wafer support body comprises a recess portion configured to support the wafer, and
the outlet is formed on the recess portion and in fluid communication with the first plenum.

6. The susceptor assembly according to claim 5, wherein the wafer support further comprises an annular ridge on the recess portion, and
said annular ridge is concentric with a circumference of the wafer to be treated.

7. The vacuum susceptor assembly according to claim 6, wherein the annular ridge is configured to be disposed within a perimeter of the wafer to be treated.

8. The susceptor assembly according to claim 6, wherein the outlet is formed along an outermost periphery of the annular ridge.

9. The susceptor assembly according to claim 6, wherein a depth of the recess portion at an outer diameter side of the annular ridge is deeper than an inner diameter side of the annular ridge and progressively decreased toward a perimeter of the cylindrical body.

10. The susceptor assembly according to claim 5, further comprising:
a second plenum channel formed at the outer portion of the wafer support, the second plenum channel positioned vertically apart from the first plenum in a thickness direction of the wafer support body, and
a plurality of secondary purge holes providing fluid communication between the first plenum channel and the second plenum channel,
wherein a plurality of first purge holes are in fluid communication with the second plenum channel and respective purge channels.

11. The susceptor assembly according to claim 10, wherein a number of the second purge holes is greater than a number of the first purge holes.

12. The susceptor assembly according to claim 2, wherein the susceptor assembly is coupled to a shaft which comprises a vacuum tube and an inner gas supply tube, and
a plurality of purge gas supply holes are configured to be fluidly connected to an inert gas source through the inner gas supply tube.

13. The susceptor assembly according to claim 12, further comprising:
a vacuum chuck groove disposed at the inner portion of the wafer support; and
a vacuum chuck hole in fluid communication with a plurality of vacuum chuck grooves through the vacuum tube, wherein the vacuum chuck hole is configured to be in fluid connection with a vacuum source.

14. A susceptor assembly, comprising:
a wafer support configured to support a wafer, wherein the wafer support comprises:
a wafer support body configured to support a wafer to be treated;
a plurality of purge channels extending laterally from an inner portion of the wafer support body to an outer portion of the wafer support body;
a first plenum channel disposed at the outer portion of the wafer support;
a second plenum channel positioned vertically apart from the first plenum, wherein the second plenum channel is in fluid communication with the plurality of purge channels by way of a plurality of first purge holes and is in fluid communication with the first plenum by way of a plurality of second purge holes; and
an outlet in fluid communication with the first plenum to deliver purge gas to an edge of the wafer.

15. The susceptor assembly according to claim 14, wherein the wafer support body comprises a recess portion configured to support the wafer, and
the outlet is formed on the recess portion and in fluid communication with the first plenum.

16. The susceptor assembly according to claim 14, wherein the susceptor assembly is coupled to a shaft which comprises a purge gas supply tube connected to an inert gas source.

17. The susceptor assembly according to claim 16, further comprising:
a heater pedestal coupled to the shaft which comprises one or more vacuum tubes and one or more inner gas supply tubes, wherein the heater pedestal comprises one or more vacuum holes configured to couple to a respective vacuum tube in the shaft and one or more purge gas holes configured to couple to a respective inner gas supply tube in the shaft.

18. The susceptor assembly according to claim 17, wherein the one or more vacuum holes are configured to be fluidly connected to a vacuum source through the respective vacuum tube, and
wherein the one or more purge holes are configured to be fluidly connected to an inner gas source through the respective inner gas supply tube.

19. A showerhead assembly for treating a wafer, comprising:
a showerhead plenum;
a plurality of openings in fluid communication with the showerhead plenum, the plurality of openings configured to convey vaporized precursor(s) from the showerhead plenum and onto a wafer support configured to support the wafer; and
a plurality of edge purge injection holes configured to be disposed outside of a perimeter of the wafer to be treated and in fluid communication with a purge gas source, the plurality of edge purge injection holes arranged to direct a purge gas to prevent back-diffusion of gases to the wafer.

20. The showerhead assembly according to claim 19, wherein the edge purge injection holes are not in fluid communication with the showerhead plenum.
